(19) United States
(12) Patent Application Publication
(10) Pub. No.: US 2017/0229176 A1
(43) Pub. Date: Aug. 10, 2017

(54) SEMICONDUCTOR STORAGE DEVICE, AND STORAGE DEVICE USING SAME

(71) Applicant: HITACHI, LTD., Chiyoda-ku, Tokyo (JP)

(72) Inventors: Kenzo KUROTSUCHI, Tokyo (JP); Yoshitaka SASAGO, Tokyo (JP)

(73) Assignee: Hitach, Ltd., Tokyo (JP)

(21) Appl. No.: 15/502,352

(22) PCT Filed: Sep. 9, 2014
(86) PCT No.: PCT/JP2014/074873

§ 371 Date: Feb. 7, 2017

(51) Int. Cl. G11C 13/00

(52) U.S. Cl. CPC G11C 13/0069; G11C 13/0004; G11C 13/0061; G11C 13/0064; G11C 13/0097

(57) ABSTRACT

In a semiconductor recording device, a writing time as long as in the case where the number of bits to be subjected to ‘0’ writing is large even in the case where the number of bits to be subjected to ‘0’ writing in page writing is small. A population counter that controls the number of ‘0’ bits is provided. In addition, a writing driver is divided into a plurality of sub-writing drivers. In this configuration, as many sub-writing drivers as possible are driven as long as the number of ‘0’ writing bits is equal to or smaller than the maximum number of bits that can be simultaneously written.

### TECHNICAL FIELD

The present invention relates to a semiconductor storage device and to a storage device using the same. Particularly, the present invention relates to a technique applicable to an electrically-rewritable nonvolatile memory such as a phase change memory, a ReRAM (Resistive Random Access Memory), or an STT-MRAM (Spin Transfer Torque-Magnetoresistive Random Access Memory).

### BACKGROUND ART

JP2010-182373 A (PTL 1) discloses a background art of the present technical field. This publication discloses, as an object, “improving a program throughput while reducing the total amount of writing current”. Further, this publication discloses the following as a solution to a problem: “A driving circuit of the memory cell repeats a cycle of verify-writing operations of data while setting a memory cell corresponding to N bit as one writing cell unit until all the cells pass the verification. In this case, a plurality of verify-writing operations are simultaneously executed with memory cells that have not passed the verification as targets of the operations.” (see Abstract). Further, this publication discloses: “This control is possible because the possibility of passing the verification (programming success rate) can be made approximately constant between memory cells with such high controllability as illustrated in FIG. 4.” (see paragraph 0061).

In addition, JP2007-188552 A (PTL 2) is provided. This publication discloses, as an object, “providing a semiconductor storage device capable of shortening time required for batch verification processing and accelerating buffer writing”. Further, this publication discloses the following as a solution to a problem: “A semiconductor storage device executes writing processing on memory cells in an address region, executes batch verification processing of collectively performing verification operations for plural addresses, and executes repetition of the batch verification processing and the writing processing. The semiconductor storage device includes a detector that detects whether or not each address includes a memory cell that has not been subjected to the writing, and executes, in at least a part of the batch verification processing, verification processing by excluding at least a part of addresses that have been determined as not including a memory cell that has not been subjected to the writing in verification processing of the last time or the time before.

Further, a technique of manufacturing a large-capacity semiconductor storage device by using a phase change memory as the nonvolatile memory and connecting plural bits in series and in a chain shape is known (for example, see PTL 3). This publication discloses: “Concerning a semiconductor memory in which a diode and a transistor are connected in series, there is a problem that the properties of the transistor degrade due to a carrier injected from the diode into the transistor.” (see Abstract). Further, this publication discloses in paragraph [0044]: “For example, in a cell in which memory cells including a transistor and a phase change element connected in parallel are connected in series, that is, a chain cell, the following operation is executed”.

### CITATION LIST

### Patent Literature

PTL 1: JP 2010-182373 A
PTL 2: JP 2007-188552 A
PTL 3: JP 2012-69830 A

### SUMMARY OF INVENTION

### Technical Problem

The present inventors carried out detailed examination on variable resistance memories, especially phase change memories, and found the following. By contrast with a charge storage type such as a NOR type flash memory disclosed in PTL 1, which is capable of being subjected to successive injection of charges, the programming success rate of a phase change memory varies depending on property variations between cells and physical arrangement of the cells. Therefore, it is difficult to employ the control method based on the approximately constant programming success rate disclosed in PTL 1.

Further, the present inventors carried out detailed examination on data stored in a semiconductor storage device and found the following. For example, the data is transmitted from a server to a storage controller device via a storage area network constituted by a fiber channel, and is further transmitted to an SSD (Solid State Drive) via an SAS (Serial Attached SCSI) or the like. The SSD includes an SSD controller and the semiconductor storage device. The data is first transmitted to the SSD controller and then to the semiconductor storage device to be stored. Here, the size of the data the server transmits is an integral multiple of a sector size. The sector size is 512 B or 4 KB. According to an analysis by the present inventors, the size of data used by the server is in most case smaller than the sector size, and, in this case, the server performs padding processing of adding to required data data in which plural ‘0’ s or ‘1’ s are successively arranged to convert the required data into data having a size equal to or integral multiple of the sector size, and then transmits the required data. Thus, data partially including a series of ‘0’s or ‘1’ s may be sometimes transmitted to the storage controller device or the SSD controller. In this case, it becomes possible to write a large amount of data of successively arranged ‘1’s into the semiconductor storage device by performing appropriate data conversion processing in the storage controller device or the SSD controller device. Meanwhile, in the case where a value indicating an erased state is ‘1’ and a value after writing is ‘0’ in the semiconductor storage device, the value of a memory element after erasing is ‘1’, and thus the semiconductor storage device may perform ‘0’ writing on the memory element only when the ‘0’ writing is instructed. However, writing speeds at times when many ‘1’ s were written and when many ‘0’ s were written were the same even though the number of bits actually written on memory cells and the total of the writing current were smaller for the former. When many ‘1’ values are written in the writing, the number of bits written as ‘0’ is small, and thus power consumption for the writing is smaller than when many ‘0’ values are written.

That is, there is a problem that writing time approximately as long as in the case were many ‘0’ values are written is also required in the case where many ‘1’ values are written even though it is possible to perform such control that many ‘1’ values are written on the semiconductor storage device.

### Solution to Problem

To solve the problem above, the present disclosure includes a plurality of means for solving the problem above. One example of them is a semiconductor storage device which includes a plurality of memory cells that stores ‘0’ and ‘1’ by using a difference in electrical resistance and a counter circuit that counts, while regarding a predetermined number of the memory cells as a writing unit, for a plurality of writing units, the number of ‘0’ bits written on the writing unit and in which one or plural writing units are selected such that the number of ‘0’ bits is smaller than a predetermined number and data is collectively written.

Another aspect of the present invention is a semiconductor storage device including a memory array constituted by a plurality of memory cells and a plurality of sub-writing drivers that executes at least one of writing (write), erasing, and verify-writing of data on a predetermined number (a constant that is a natural number) of memory cells. Writing (write), erasing, and verify-writing, and the like of data are similar operations in changing the state of a predetermined number of memory cells, and thus these will be sometimes collectively referred to as “setting” implying setting of states of memory cells in the present description for simplicity.

The state of the memory cells is interchangeable between at least two states, and stored data can be kept or changed by keeping or changing each state of a predetermined number of memory cells by the setting operation. For controlling the states of arbitrary memory cells, in a typical example, a local selection line connected to a gate electrode of a selection transistor of a memory cell is driven by a driver in a memory array. However, it is not limited to this.

The two states corresponds to “1” and “0” of the data, for example. To which of “1” and “0” of data states of the memory cell, for example, a high-resistance state and a low resistance state, correspond is arbitrarily selected. To which of a recorded state and an erased state “1” and “0” of data correspond is also arbitrarily selected. In addition, the present invention is also applicable to memory cells capable of storing so-called multiple values, which include not only “1” and “0” but three or more values.

Examples of typical memory cells include memory cells configured to store information by using resistance values varying in accordance with microscopic change in states of materials, such as phase change and change in spin states. For example, these are called as phase change memories, ReRAMs, or spin transfer torque magnetoresistive memories.

In setting of data, the number (a variable that is a natural number) of memory cells whose states are to be changed among memory cells of a predetermined number (normally a constant that is a natural number, but may be different between sub-writing drivers) set by a sub-writing driver is counted for each of the sub-writing drivers. The memory cells whose states are to be changed correspond to, from the perspective of stored data, memory cells in which “0”s are changed to “1”s or “1”s are changed to “0”s, for example. In addition, from a physical perspective, it refers to change in resistance values of the memory cells, for example.

Next, a sub-writing driver is selected such that the total number of memory cells whose states are to be changed does not exceed the predetermined number (a constant that is a natural number). A single sub-writing driver or a plurality of sub-writing drivers may be selected. Thus, the setting is simultaneously performed by the selected sub-writing driver. Here, “simultaneously” includes controlling the selected sub-writing driver using the same control signal. In the case where the number of sub-writing drivers simultaneously operated is restricted due to the power consumption, an upper limit (a constant that is a natural number) may be provided for the number of sub-writing drivers to be selected.

Another aspect of the present invention includes a plurality of memory cells capable of setting a first memory state and a second memory state by using a difference in electrical resistance and a counter circuit that counts, while regarding a predetermined number of the memory cells that are a part of the plurality of memory cells as a writing unit, for a plurality of writing units, the number of memory cells whose memory states are changed when at least one (hereinafter referred to as setting) of writing (write), erasing, and verify-writing is performed on the memory cells in the writing unit. One or plural writing units are selected on the basis of a calculation result by the counter circuit such that the number of memory cells is equal to or smaller than a predetermined number, and data of the selected one or plural writing units are collectively set.

Yet another aspect of the present invention is a semiconductor storage device including a plurality of memory cells capable of setting a first memory state and a second memory state by using a difference in electrical resistance and a counter circuit that counts, while regarding a predetermined number of the memory cells as an erasing unit, for the erasing unit, the number of first memory states to be erased, wherein one or plural erasing units are selected on the basis of a calculation result by the counter circuit such that the number of first memory states is equal to or smaller than a predetermined number, and data in the selected one or plural erasing units are collectively erased.

It should be noted that a third memory state or memory states of a higher ordinal number may be added in the case where the first memory state and the second memory state are mentioned in the present description.

Yet another aspect of the present invention includes a plurality of memory cells capable of storing a plurality of memory states, a plurality of sub-writing drivers connected to a predetermined number of memory cells among the plurality of memory cells and capable of changing memory states of the predetermined number of memory cells, an input path for inputting data to the sub-writing drivers, and a counter. The counter counts the number of memory cells whose memory states are to be changed by the plurality of sub-writing drivers on a basis of the input data among the predetermined number of memory cells. An operation timing of the plurality of sub-writing drivers is controlled on the basis of a counting result of the counter.

In an example of a specific configuration, the counter counts, for each of the plurality of sub-writing drivers, the number of memory cells whose memory states are to be changed, adds up results of the counting, and, in a case where the results of the counting that have been added up exceeds a first predetermined threshold value at an n-th (n is a natural number) sub-writing driver, collectively causes sub-writing drivers with ordinal numbers equal to or smaller than n−1 to operate.

In a preferable embodiment, in the case where the results of the counting that have been added up does not exceed the first predetermined threshold value at the n-th (n is a natural number) sub-writing driver but the n has reached a second predetermined threshold value, sub-writing drivers with ordinal numbers equal to or smaller than n are collectively caused to operate.

In a more preferable embodiment, counting for the sub-writing drivers with ordinal numbers equal to or larger than n is performed in parallel while the sub-writing drivers with ordinal numbers equal to or smaller than n−1 are collectively caused to operate. The driver to be counted in parallel is not necessarily the n-th driver, and may be a driver with an ordinal number equal to or larger than n+1 in the case where the counting for the n-th driver has been already finished.

Another aspect of the present invention is a storage device including a semiconductor storage device and a controller that controls the semiconductor storage device. Here, the semiconductor storage device includes a plurality of memory cells capable of storing a plurality of memory states by using a difference in electrical resistance, a plurality of sub-writing drivers connected to a predetermined number of memory cells among the plurality of memory cells and capable of changing memory states of the predetermined number of memory cells, an interface for communicating with the controller to input data to the sub-writing drivers, and a counter that counts a number of memory cells whose memory states are to be changed by the plurality of sub-writing drivers on a basis of the input data among the predetermined number of memory cells. In addition, the controller includes an I/O portion for communicating with the semiconductor storage device and a higher-order device, and a control portion that controls at least one of writing, erasing, and verification of data for the semiconductor storage device, and an operation timing of the plurality of sub-writing drivers is controlled on a basis of a counting result of the counter.

According to a preferable embodiment, the controller can invert a first value and a second value of data received from the higher-order device and perform control for causing the inversion to be reflected on the memory cells of the semiconductor storage device.

Further, specific examples of the operation of the storage device described above are as follows.

In writing of data, the sub-writing drivers perform data writing of changing a state of a designated memory cell from a first value to a second value among the predetermined number of memory cells that has been subjected to erasing by being wholly set to the first value, and the counter counts a number of the memory cells to be changed from the first value to the second value to control the operation timing of the sub-writing drivers.

The sub-writing drivers perform verify-writing of changing memory cells that have not been correctly changed to the second value among the memory cells to be changed from a first value to a second value to the second value again in verify-writing performed in a case where verification of stored data is performed after data writing and an error is found, and the counter counts the number of memory cells that have not been correctly changed to the second value to control the operation timing of the sub-writing drivers.

The sub-writing drivers perform data writing or erasing of changing a state of a designated memory cell on the basis of the input data in the writing or erasing of the data, and the counter compares data based on a current state of a memory cell with the input data, and counts the number of memory cells to be changed from a first value to a second value for performing the data writing or erasing on a basis of the input data to control the operation timing of the sub-writing drivers.

### Advantageous Effects of Invention

A semiconductor storage device high in data writing rate and low in peak current consumption can be realized.

Technical problems, configurations, and advantageous effects other than what has been described above will be made clear in the description of embodiments below.

### BRIEF DESCRIPTION OF DRAWINGS

FIG. 1 is a block diagram illustrating an exemplary configuration of a semiconductor storage device 101 according to a first exemplary embodiment of the present invention.

FIG. 2 is a flowchart illustrating an exemplary writing sequence according to the first exemplary embodiment of the present invention.

FIG. 3 is a table illustrating examples of sub-writing driver numbers and an order of writing according to the first exemplary embodiment of the present invention.

FIG. 4 is a sequence chart illustrating an exemplary operation sequence of a population counter and sub-writing drivers according to the first exemplary embodiment of the present invention.

FIG. 5 is a block diagram illustrating an exemplary configuration of the semiconductor storage device 101 according to the first exemplary embodiment of the present invention.

FIG. 6 is a plan view illustrating an exemplary configuration of a memory array according to the first exemplary embodiment of the present invention.

FIG. 7 is a circuit diagram illustrating an exemplary circuit configuration of a portion of the memory array according to the first exemplary embodiment of the present invention.

FIG. 8 is a table illustrating examples of states of X and Y selection lines and selection states of memory chains according to the first exemplary embodiment of the present invention.

FIG. 9 is a schematic section view of a portion of the memory array according to the first exemplary embodiment of the present invention.

FIG. 10 is a schematic plan view of a portion of the memory array according to the first exemplary embodiment of the present invention.

FIG. 11 is a graph illustrating an exemplary operation sequence according to the first exemplary embodiment of the present invention.

FIG. 12 is a circuit diagram illustrating an exemplary circuit configuration according to the first exemplary embodiment of the present invention.

FIG. 13 is a schematic diagram illustrating an exemplary writing sequence according to the first exemplary embodiment of the present invention.

FIG. 14 is a table illustrating examples of on/off states of the Y selection line and operations according to the first exemplary embodiment of the present invention.

FIG. 15 is a circuit diagram illustrating an exemplary circuit configuration for comparison with the first exemplary embodiment of the present invention.

FIG. 16 is a block diagram illustrating an exemplary configuration of the semiconductor storage device 101 according to the first exemplary embodiment of the present invention.

FIG. 17 is a graph illustrating an exemplary operation of a memory element according to the first exemplary embodiment of the present invention.

FIG. 18 is a flowchart illustrating an exemplary operation sequence according to a second exemplary embodiment of the present invention.

FIG. 19 is a flowchart illustrating an exemplary operation sequence according to a third exemplary embodiment of the present invention.

### DESCRIPTION OF EMBODIMENTS

Exemplary embodiments will be described below with reference to drawings. It should be noted that the present invention should not be interpreted limitedly from the description of the exemplary embodiments that will be shown below. One of ordinary skill in the art should easily understand that the specific configuration may be changed within the scope of the idea or the gist of the present invention.

In the configuration of invention that will be described below, the same reference letters may be used for the same component or components having similar functions in different drawings, and redundant descriptions may be omitted.

Descriptions of “first”, “second”, “third”, and the like in the description and the like are given to identify constituents and do not necessarily restrict the number or the order. In addition, numerals for identifying constituents are used for each context, and a numeral used in one context does not necessarily indicate the same constituent in another context. Moreover, a constituent identified by one numeral should not be prevented from also having a function of a constituent identified by another numeral.

The position, size, shape, range, and the like of each constituent indicated in drawings and the like may not represent an actual position, size, shape, range, or the like for easier understanding of the invention. Thus, the present invention is not necessarily limited to positions, sizes, shapes, ranges, or the like disclosed in drawings or the like.

### First Exemplary Embodiment

In the present exemplary embodiment, an example of a semiconductor storage device 101 including a population counter 103 will be described.

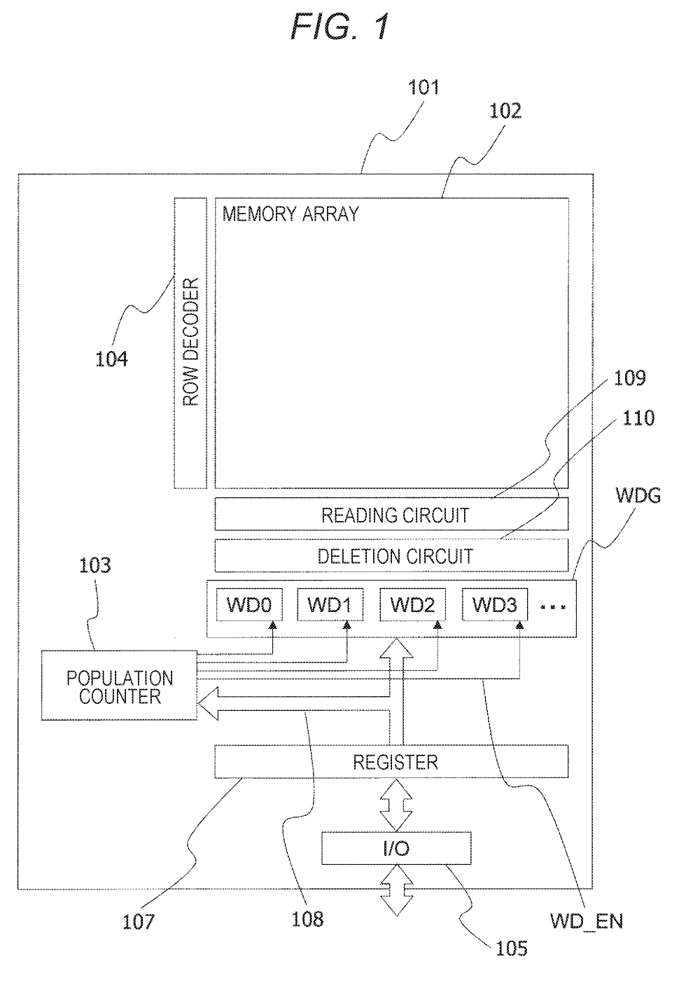

FIG. 1 is a block diagram illustrating an exemplary configuration of a semiconductor storage device 101 according to the present exemplary embodiment.

Data of ‘0’ or ‘1’ is transmitted to the semiconductor storage device 101, and the semiconductor storage device 101 holds the value thereof. Multiple-value control is also possible by transmitting ‘2’ or ‘3’. Multiple-value control has a merit of improving the speed of data transfer.

Here, control of transmitting relatively more ‘1’ values than ‘0’ to the semiconductor storage device 101 is possible. Of course, it goes without saying that the received data can be held in the semiconductor storage device 101 by inverting the values of ‘1’ and ‘0’. This case has a merit that the configuration of an external control device controlling the semiconductor storage device 101 can be simplified. Further, it is also possible to control, by rewriting a configuration register in the semiconductor storage device 101, whether the values are to be inverted. This case has a merit that the configuration of the external control device controlling the semiconductor storage device 101 has a redundancy and more control devices can be made compatible in a short period of time.

An exemplary case of the semiconductor storage device 101 having an erasing operation and a writing operation will be described below. The erasing operation is performed on a block unit basis and sets the values of all the bits included in the block to ‘1’. Meanwhile, the writing operation is performed on a page basis, which is smaller than the block, and sometimes sets the value of a bit included in the page to ‘0’ in accordance with data to be written.

A peak current that can be consumed by the semiconductor storage device 101 requires to be restricted to be equal to or lower than a certain amount. For example, supposing a use for an SSD, a power source device for the semiconductor storage device 101 in the SSD needs to be designed in consideration of a maximum peak current amount described in a data sheet of the semiconductor storage device 101. If the semiconductor storage device 101 consumes a current of an amount equal to or larger than the maximum peak current amount described in the data sheet, a power source voltage may lower and a malfunction of not only the semiconductor storage device 101 but also the SSD or a storage system including a plurality of SSD may be caused.

In a memory cell that requires a large amount of current for rewriting bits, for example, a phase change memory, a ReRAM, or an STT-RAM, most of the current consumed by the semiconductor storage device 101 is consumed for a writing current for bits. In more detail, boosting and stepping down of the power source voltage are performed in the semiconductor storage device 101, and thus it needs to be examined not only from the perspective of the amount of current but also from a perspective also including the power and a boosting loss. For example, assuming that the amount of current required for rewriting a bit is 40 uA (microampere) per bit, the total amount of current consumption for simultaneously perform writing on 32 bits is 1280 uA. Assuming that a boosting efficiency is 10%, the amount of consumed power source current is 12.8 mA. Assuming that the peak amount of current consumption is 25 mA, 51% of the amount of current consumed in the whole tip is consumed for rewriting.

As has been already described, control of transmitting relatively more ‘1’ values than ‘0’ to the semiconductor storage device 101 is possible. A region with more ‘1’ values is characterized in that less bits are subjected to bit inversion from ‘1’ to ‘0’ by passing a writing current in the writing operation at this time.

Therefore, the semiconductor storage device 101 of the present exemplary embodiment transmits, at the same time as transmitting a value of data to be written on a memory array 102 stored in a register 107 to a sub-writing driver WD0, the same data to the population counter 103. The population counter 103 performs population counting of counting the number of ‘1’s included in data, and the number of bits to be subjected to bit inversion from ‘1’ to ‘0’ is calculated based on the results thereof. In the case where the number of bits to be subjected to the bit inversion is smaller than a predetermined number, data is further transmitted from the register to the next sub-writing driver WD1, and the same data is simultaneously transmitted to the population counter 103. Then, the population counter calculates the number of bits to be subjected to the bit inversion from ‘1’ to ‘0’. In this way, the number of bits to be subjected to bit inversion is restricted to be equal to or smaller than a certain number, and the number of bits simultaneously written is increased by driving as many of a plurality of sub-writing drivers WD as possible under the restriction. According to this configuration, the data writing rate can be improved.

The population counter 103 is a control part that performs processing of population counting (sometimes described as Hamming weight) of counting the number of ‘1’ bits included in data. For example, in the case where data is 115, that is, 01110011 in binary, the counted number of ‘1’s of this data is 5.

When writing on the semiconductor storage device 101, a writing command and data to be written is transmitted from a host to the semiconductor storage device 101. The semiconductor storage device 101 receives the data via an I/O portion 105 and stores the data in the register 107.

The data stored in the register 107 is transmitted to the population counter 103 and a writing driver group WDG through a data bus 108. The writing driver group WDG is constituted by the plurality of sub-writing drivers WD. The population counter includes signal lines WD_EN for activating respective sub-writing drivers.

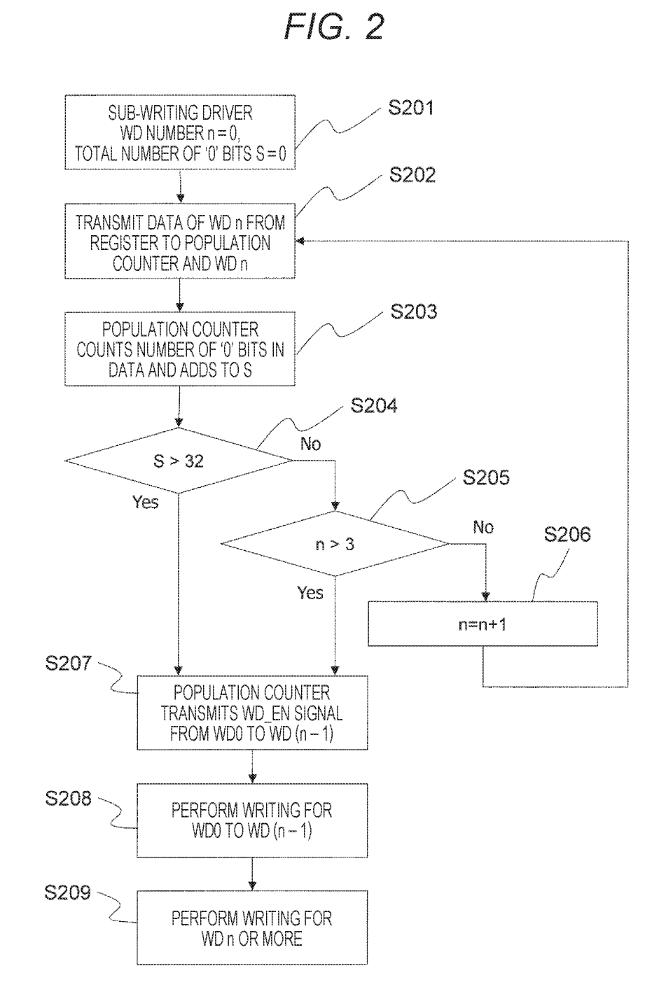

A writing sequence of the semiconductor storage device 101 according to the present exemplary embodiment will be described with reference to FIG. 2.

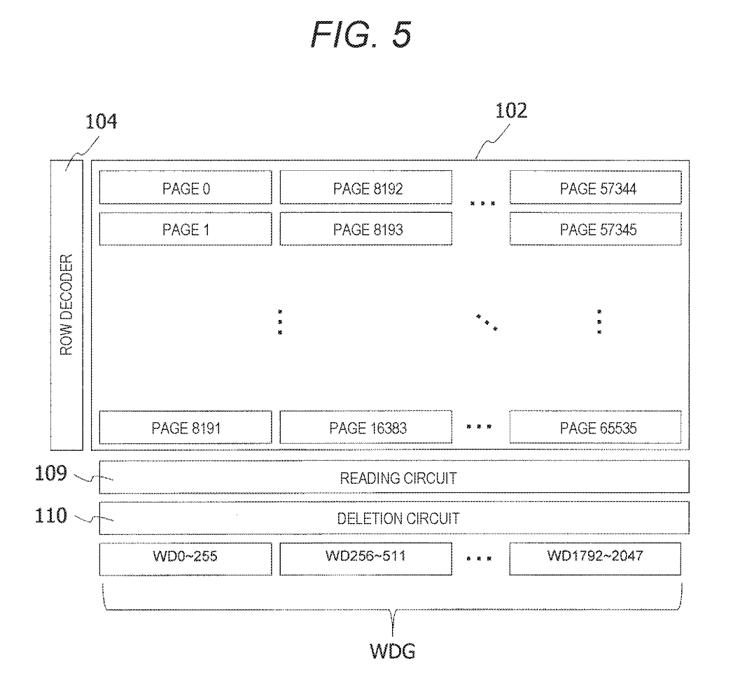

A case of perform writing on a page 0 (the page configuration will be described later using FIG. 5) will be described as an example. The number of sub-writing drivers WD connected to the region of the page 0 is 256, and among these, at most four and at least one sub-writing driver WD is driven at the same time. That is, the maximum number of sub-writing drivers simultaneously driven is 4. One sub-writing driver is capable of performing writing on at most 32 bits at the same time. To keep the peak current of the semiconductor storage device 101 at or below a certain level, the number of bits that can be subjected to writing simultaneously is set to be 32 or smaller. That is, the maximum number of bits that can be subjected to writing simultaneously is 32. In addition, the page size is set to be 8 KB and the block size is set to be 128 KB. The page size may not be a multiple of 2 and may be, for example, 9 KB by adding ECC or a supplementary area capable of storing reliability information and a logical address. This case has an advantageous effect that the number of times of access by the SSD controller to the semiconductor storage device 101 can be reduced and thereby a high-speed SSD can be provided.

In FIG. 2, first, as the writing sequence, the value of a variant n that holds the number of sub-writing drivers WD is set to 0 and the value of a variant S that holds the number of bits S to be subjected to writing is initialized to 0 (S201). Next, 32 bits in the beginning of data stored in the register 107 is transmitted to the population counter 103 and the sub-writing driver WD0 (S202). In the case where its value is 3,346,497,239, that is, 11000111011101110111111011010111 in binary, 23 bits of ‘1’ are included in this data of 32 bits. Since its data width is 32 bit, it should be construed that the number of ‘0’ bits is 32−23=9. The population counter counts the number of ‘0’ bits in the data, and adds the result to S (S203). At this time, the value of S becomes 9. Further, whether the value of S is smaller than 32, which is the maximum number of bits that can be written simultaneously, is determined (S204). In the case where S is smaller, the process proceeds to S205 because another sub-writing driver may be further driven. Next, sub-writing driver numbers are checked and whether the maximum number (4 in the example of FIG. 2) of sub-writing drivers simultaneously driven is not reached is confirmed (S205). If the maximum number of sub-writing drivers simultaneously driven is not reached, the process proceeds to S206. Further, 1 is added to the sub-writing driver number n, and preparation for a process for the next sub-writing driver is performed (S206).

In this way, the number of sub-writing drivers WD that can be simultaneously driven is investigated by using the population counter 103.

Next, the population counter 103 transmits a signal WD_EN for activating the sub-writing drivers WD to sub-writing drivers WD that can be simultaneously driven (S207). In this example, sub-writing drivers WD0, WD1, and WD2 are activated. The sub-writing drivers WD simultaneously performs writing by receiving the activation signal WD_EN (S208). It is assumed that writing time per bit is 10 ns (nanosecond). In this case, the writing current application time for 96 bits in the beginning of the page is 10 ns in total. In this way, writing for ‘0’ bits included in the sub-writing drivers WD0 to 2 is performed. In this example, 23 bits recording the value of ‘1’ are rewritten into ‘0’. The maximum number of bits that can be written simultaneously is 32, and it can be seen that control under the number is successful.

Further, in a similar way, writing for sub-writing drivers WD of numbers equal to or larger than n, that is, equal to or larger than WD3 is performed (S209). In this way, writing is performed on a page having a data size of 8 KB.

Comparison is made with a conventional control method in terms of a writing current application time. In the conventional control method, since WD0, 1, and 2 are driven sequentially, the writing current application time for 96 bits in the beginning of the page is 30 ns in total. Meanwhile, it can be seen that the writing current application time is shortened to, for example, one third by using the present control method. That is, it can be seen that the data writing rate is improved.

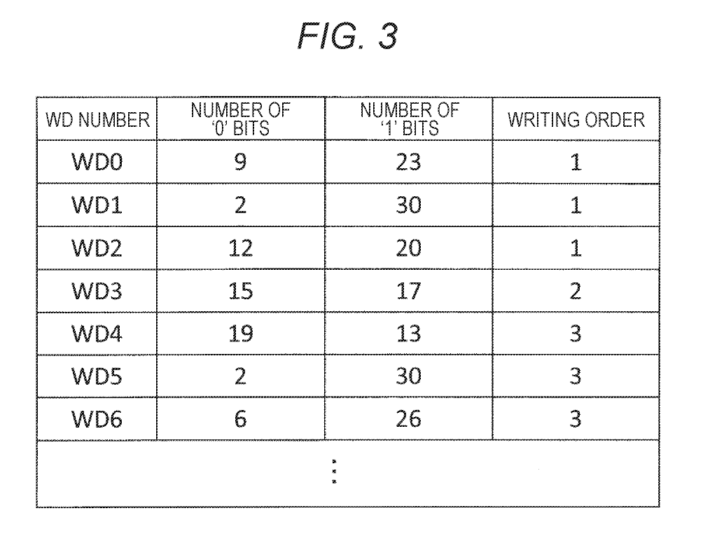

A breakdown of sub-writing driver WD numbers and the numbers of ‘1’ bits and ‘0’ bits in 32-bit data that the sub-writing drivers WD can write at the same time, and the order of writing determined by the population counter 103 will be described with reference to FIG. 3.

The sub-writing drivers WD0, 1, and 2 come first in the writing order, and it can be seen that these are subjected to writing at the same time. The number of ‘0’ bits included in WD0 to 2 is 23 in total, and the maximum number of bits that can be written simultaneously is 32 or smaller. Thus these can be subjected to writing at the same time. However, the number of ‘0’ bits included in WD0 to 3 is 38 in total and exceeds 32, which is the maximum number of bits that can be written simultaneously. Thus these cannot be subjected to writing at the same time. Therefore, writing for WD3 is performed after the completion of writing for WD0 to 2.

Next, the number of ‘0’ bits included in WD3 is 15 and does not exceed 32, the maximum number of bits that can be written simultaneously. However, it becomes 34 when summed up with 19, the number of ‘0’ bits included in WD4 that comes next, and exceeds 32, the maximum number of bits that can be written simultaneously. Due to this, WD3 and WD4 cannot be subjected to writing at the same time, and only writing for WD3 is performed second in the writing order. The subsequent of WD4 is processed in a similar manner, and data of one page is written.

As described above, the peak current of the device can be controlled to be equal to or lower than a certain value by a function of a counter circuit controlling the number of memory cells simultaneously subjected to setting or the number of sub-writing drivers WD simultaneously driven.

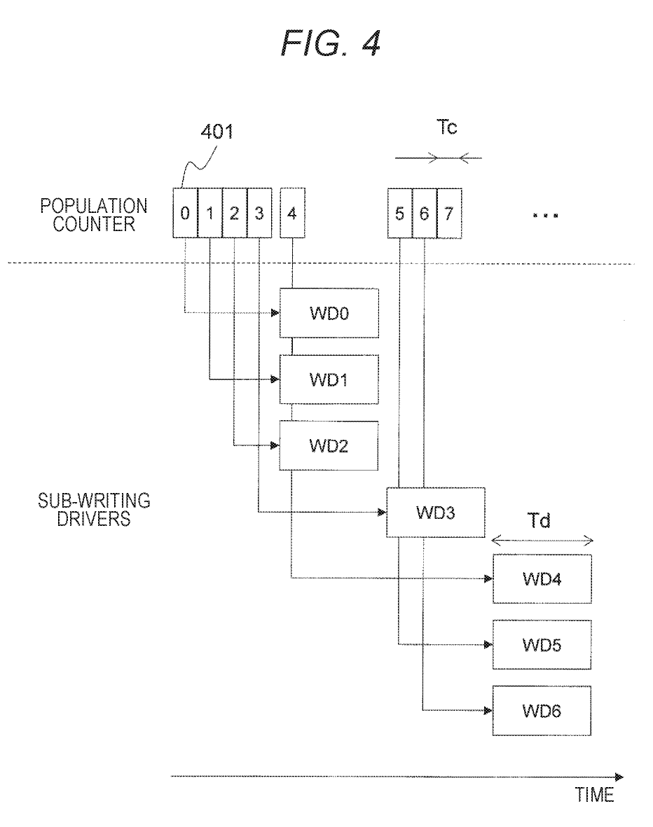

Processes performed by the population counter 103 and the order of writing processes performed by the sub-writing drivers WD in the example illustrated in FIG. 3 will be described with reference to FIG. 4. The horizontal direction corresponds to a temporal axis, portions enclosed by quadrilaterals represent processes by the population counter 103 and the writing processes by the sub-writing drivers WD, and the length of sides of the quadrilaterals in the horizontal direction represents processing time. In the figure, Tc indicates the processing time by the population counter 103, and Td indicates the writing time (time during which the driver is active) by the sub-writing drivers WD.

The population counter 103 divides 8 KB page data into 4 B data pieces from the beginning thereof, and sequentially processes the data pieces. Time required for a population counter process on one data piece 401 is, for example, 2.5 ns. By designing to define the population counter processing time so as to satisfy formula (1) below, it becomes possible to hide the population counter processing except for a process for the first writing. As a result of this, the semiconductor storage device 101 high in data writing rate can be realized.

writing time>population counter processing time×maximum number of sub-writing drivers simultaneously driven (1)

To be noted, the same relationship holds not only for the writing time but also for erasing time and verify-writing time.

The population counter 103 determines, by processing data pieces 401-0, 1, 2, and 3, that, although the sub-writing drivers WD0, 1, and 2 can be simultaneously driven, WD0, 1, 2, and 3 cannot be driven simultaneously. Thus, the population counter activates WD0, 1, and 2, and performs a writing operation. In parallel with the writing operation for WD0, 1, and 2 being performed, the population counter 103 performs processing for the next data 401-4. As a result of this, the population counter 103 activates WD3. Subsequently, while the writing operation for WD3 is performed, the population counter 103 performs processing for the next data 401-5, 6, and 7.

As described above, by performing the processing by the population counter 103 and the writing processing by the sub-writing drivers WD at the same time, it becomes possible to hide the processing time by the population counter and to improve the data writing rate.

Next, the semiconductor storage device 101 of the present proposal will be shown in further detail.

The relationship between physical positional relationships between the sub-writing drivers WD and the memory cells will be described with reference to FIG. 5.

The memory array 102 includes memory cells of 128 Gb (gigabit). To be noted, 8 bit is 1 byte. The memory array 102 is divided into pages 0 to 65,535 as illustrated in FIG. 5. The memory cells of the present exemplary embodiment are laminated on a silicon substrate in 32 layers in the direction perpendicular to the silicon substrate, and satisfy formula (2) below.

memory array capacity 128 Gb=number of pages 65,536×page size 8 KB×number of laminated layers 32 (2)

Pages 0 to 8,191 are controlled by sub-writing drivers WD0 to 255. In addition, pages 8,192 to 16,383 are controlled by sub-writing drivers WD256 to 511. When seen from a higher-order device, a writing operation performed with one access can be performed on a page unit basis. In addition, an erasing operation performed by one access can be performed on a block unit basis, the block being constituted by a plurality of pages. A row decoder 104, a reading circuit 109, an erasing circuit 110, and the like handle the memory array 102.

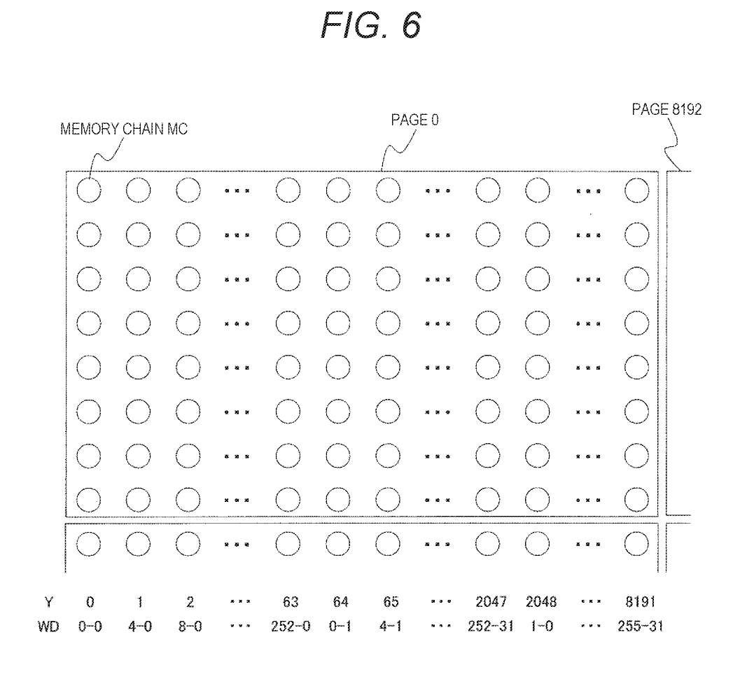

FIG. 6 is a plan view illustrating the details of the page 0 of the memory array 102 illustrated in FIG. 5.

Focusing on the page 0, Y address 0 of the memory chain MC is the zeroth bit of the sub-writing driver WD0 (described as WD0-0 in FIG. 6). Since 32 bits of sub-writing drivers WD can be simultaneously subjected to writing, WD0-0 to WD0-31 are present for WD0. Next, Y address 1 is WD4-0. Further, Y address 2 is WD8-0. The Y address of the first bit of the sub-writing driver WD0 is 64. The reason why bits of WD0 are disposed in positions apart from each other is, first, for simplify the configuration of a local driver, which is a part of drivers controlling the Y address lines, and for reducing the chip area of the semiconductor storage device 101. Next, the reason is for preventing inversion of the ‘0’ or ‘1’ value of a bit caused by a heat load occurring in bits that are not targets for writing and are near the bits to be subjected to writing as a result of bits to be subjected to writing concentrating in a partial region and the region being overheated. That is, the heat generated in writing is scattered by dispersing the bits to be subjected to writing. To be noted, the configuration described above is one exemplary embodiment, and one sub-writing driver WD can perform writing on collectively disposed bits if the merit described above is neglected.

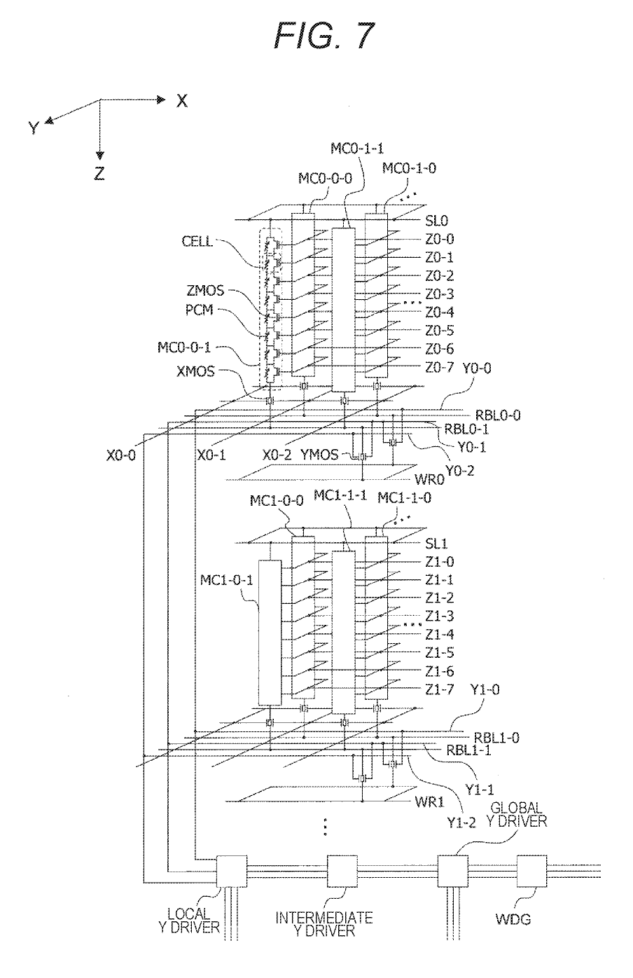

FIG. 7 is an exemplary circuit configuration of a portion of the memory array 102 of the semiconductor storage device 101 of the present exemplary embodiment. The memory array 102 is constituted by a plurality of memory chains MC. A memory chain MC is constituted by connecting a plurality of memory cells CELL in series. Here, the memory chain MC is constituted by eight memory cells CELL. A memory cell CELL is constituted by connecting one phase change element PCM and one Z selection element ZMOS in parallel. An example of one phase change element PCM and one Z selection element ZMOS connected in parallel will be described herein. However, it goes without saying that one phase change element PCM may be connected with plural Z selection elements ZMOS in parallel, plural phase change elements PCM may be connected with one Z selection element ZMOS in parallel, and plural phase change elements PCM may be connected with plural Z selection elements ZMOS in parallel.

The Z direction is a direction perpendicular to the silicon substrate, and X and Y directions are preferably perpendicular to the Z direction and to each other. According to this configuration, it becomes possible to collectively form plural memory cells arranged in the Z direction with a single process of hole boring, and thereby the producing costs can be reduced. It is preferable that a read bit line is extended in the X direction or the Y direction. The description will be given on the basis that the read bit line is extended in the X direction and is parallel to a Y selection line in the present exemplary embodiment.

An example of a memory chain laminated to four layers will be described. In this case, the number of laminated layers in the memory cell is 8×4=32. It goes without saying that the number of laminated layers may be larger than 4 or smaller than 4. A larger number of laminated layers has a merit of being able to increase the memory capacity. A smaller number of laminated layers has a merit of being able to facilitate the production.

In the present exemplary embodiment, a memory chain in a layer H having an X address of I and a Y address of J is described as MC(H)-(I)-(J). Plural read bit lines RBL are extended in the X direction. A read bit line in the Layer H having a Y address of J is described as RBL(H)-(J).

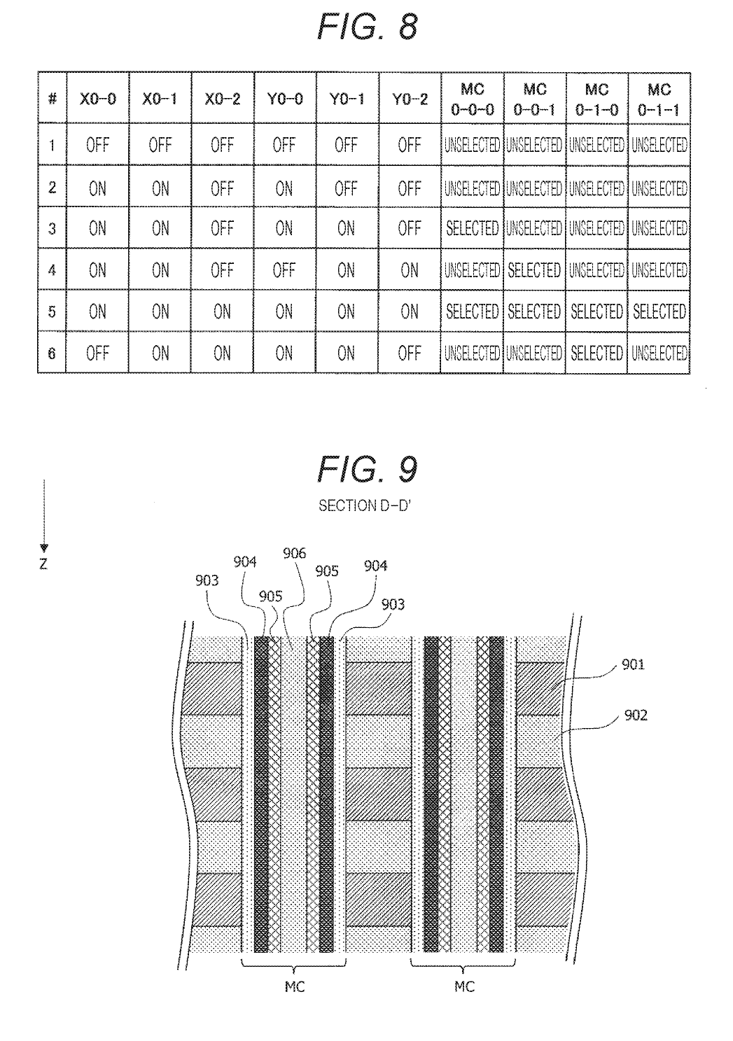

A method of selecting a memory chain MC will be described with reference to FIG. 8.

The memory chain MC is selected by using an X selection line X and a Y selection line Y. For example, as illustrated in FIG. 7, a YMOS that is a Y selection MOS for a memory chain MC0-0-0 is interposed between a Y selection line Y0-0 and a Y selection line Y0-1, and an XMOS that is an X selection MOS is interposed between an X selection line X0-0 and an X selection line X0-1. An X selection line X is connected to a gate electrode of an X selection MOS, and a Y selection line Y is connected to a gate electrode of a Y selection MOS.

The X selection MOS and the Y selection MOS are double-gate MOSes, and two gate electrodes are provided for one MOS. Further, since the channel film of the MOS is thin, the MOS is turned on only when an on voltage is applied to both of the two gate electrodes. For example, in the case where the source voltage of the MOS is −7.5, an exemplary on voltage is 0 V and an exemplary off voltage is −7.5 V. In other cases, that is, in the case where the on voltage is applied to one of the gate electrodes and the off voltage is applied to the other or in the case where the off voltage is applied to both of the two gate electrodes, the MOS is turned off. The MOS is in a low-resistance state in the case where the MOS is on, and the MOS is in a high-resistance state in the case where the MOS is off. The X selection MOS and the Y selection MOS are connected in series, and, by turning both of these on, a current flows into a source line SL from a writing electrode WR through a memory chain MC. At this time, writing for a memory cell MC in the memory chain MC is performed.

At this time, as illustrated in FIG. 8 as a case #1, if X selection lines X0-0 and X0-1 and Y selection lines Y0-0 and Y0-1 are under a voltage that turns the X selection MOS and the Y selection MOS off, for example, −7.5 V, X selection MOSes and Y selection MOSes of memory chains MC0-0-0, 0-0-1, 0-1-0, and 0-1-1 will be off, that is, in high resistance states, and the memory chains described above will be unselected.

Next, as illustrated as a case #2, X selection MOSes of the memory chains MC0-0-0 and MC0-0-1 are turned on when a voltage for turning on, for example, 0 V, is applied to the X selection lines X0-0 and X0-1 and the Y selection line Y0-0. Meanwhile, for example, an on voltage is applied to Y0-0, which is one of the gate electrodes of the Y selection MOS of MC0-0-0, and an off voltage is applied to Y0-1, which is the other of the gate electrodes. The Y selection MOS is off at this time. Therefore, MC0-0-0 is in an unselected state.

Further, as illustrated as a case #3, if an on voltage is applied to the Y selection line Y0-1, the Y selection MOSes of MC0-0-0 and MC0-1-0 will be turned on as a result of the on voltage applied to both of the gate electrodes thereof. The X selection MOS of MC0-0-0 is also on, and thus MC0-0-0 is in a selected state. However, since the X selection MOS of MC0-1-0 is off, MC0-1-0 is in an unselected state.

Subsequently, selected states described in the table are achieved by employing voltage arrangements illustrated as #4 to 6.

A Y selection line is driven by a local Y driver illustrated in FIG. 7. A signal for driving the local Y driver is driven by an intermediate Y driver. The intermediate Y driver is capable of performing conversion of a driving voltage. For example, in writing, a YMOS, which is a MOS that performs Y selection, is driven by switching between voltages of 0 V and −7.5 V. The local Y driver also utilizes the voltages of 0 V and -7.5 V, and a control signal thereof is transmitted from the intermediate Y driver. Meanwhile, the intermediate Y driver utilizes voltages of 0 V and 2.3 V and a control signal thereof is transmitted from a global Y driver. The intermediate Y driver performs signal voltage conversion by using a level shifter circuit. It is preferable that the local Y driver and the intermediate Y driver are positioned in the memory array. Meanwhile, it is preferable that the global Y driver is positioned outside the memory array. In addition, it is preferable that more intermediate Y drivers are provided than global Y drivers. According to this configuration, it becomes possible to reduce an electricity loss for conveying a control signal, and thereby the semiconductor storage device 101 with a small power consumption can be realized.

FIG. 9 illustrates a partial section view of the memory array 102.

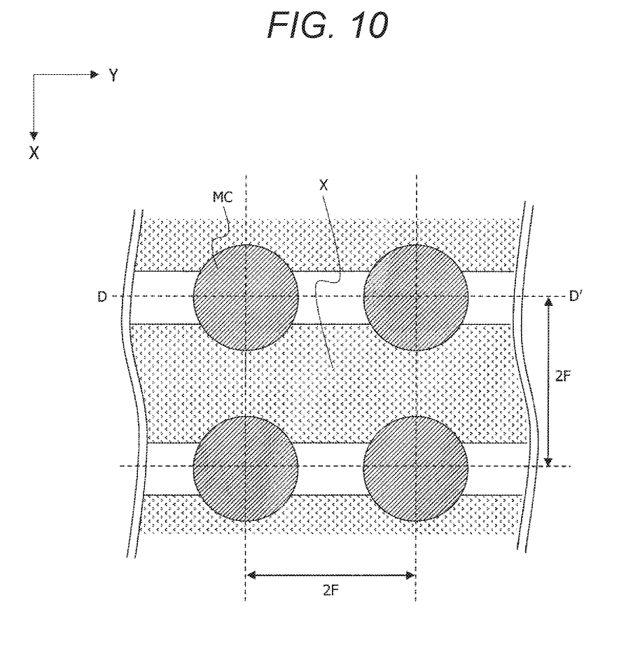

FIG. 10 illustrates a partial plan view of the memory array 102.

The memory chains MC are arranged with an interval of 2F. An X selection target is extended in the Y direction.

FIG. 9 illustrates a schematic section view of a section D-D′ illustrated in FIG. 10. A portion of the memory chain MC is illustrated.

In semiconductor elements illustrated in FIGS. 9 and 10, plural Z selection elements ZMOS and phase change elements PCM are formed. A Z selection element ZMOS and a phase change element PCM is constituted by a silicon oxide film 906, gate oxide films 903, silicon channels 904, phase change materials 905, Z selection transistor gate electrodes 901, and interlayer insulating films 902.

It is desirable that a vertical GAA-NMOSFET (Gate AllAround n-channel MOSFET) is used as the Z selection element ZMOS. By using an NMOSFET having a higher current driving performance than a PMOSFET, the number of phase change elements PCM included in the memory chain MC can be increased, and the semiconductor storage device 101 with a large capacity can be realized. Of course, it goes without saying that a PMOS can be also used. By using a vertical MOSFET, the size of a transistor can be 4F2, which is smaller than in the case where a planar MOS is used, and thus a larger capacity can be achieved. By employing a GAA structure, compared with the case where a planar MOS is used, the gate width can be increased, the driving performance of the MOS can be improved, the number of memory cells CELL included in a phase change chain MC can be increased, and thus a larger capacity can be achieved. In the case where a PMOS is used, since the voltage applied to a gate electrode of an unselected Z selection transistor can be lowered compared with the case where an NMOS is used, the gate breakdown voltage of the Z selection MOS can be lowered, and thus an advantageous effect of improving the reliability of the semiconductor storage device 101 can be achieved.

As a part of a material for a phase change element PCM, a chalcogenide material, particularly a GeSbTe alloy (germanium-antimony-tellurium alloy) may be used. A chalcogenide material can take two metastable states of amorphous (noncrystalline state) and a crystalline state, and the electric resistance thereof differs between these states. That is, it has a high resistance in an amorphous state and a low resistance in a crystalline state. The values of ‘0’ and ‘1’ can be recorded by using the difference in electric resistance. An amorphous state is set as ‘0’ and a crystalline state is set as ‘1’. Rewriting from ‘0’ to ‘1’ is set as erasing, and rewriting from ‘1’ to ‘0’ is set as writing. Rewriting is performed by passing a current through a phase change element PCM and thereby generating a Joule heat. To perform erasing, the phase change element is kept for a certain period of time at a temperature equal to or higher than a crystallization temperature to crystallize. To perform writing, it is amorphized (glassified) by being heated up to a temperature equal to or higher than a melting point and then quickly cooled down. It goes without saying that the phase change element PCM can take more than three values. Using a phase change element already applied for a product as a storage element has an advantageous effect that the period for development can be shortened and thus the semiconductor storage device 101 can be shipped in a short period of time. Although a phase change element that exhibits a crystalline-amorphous phase transition is described as an example in the present exemplary embodiment, it goes without saying that an element that exhibits a crystal A-crystal B phase transition may be also used. Here, a crystal A is a crystal having a different crystal structure from a crystal B. Although a case where a phase change element is used as a storage element is described as an example in the present exemplary embodiment, it goes without saying that a ReRAM, an STT-MRAM (spin injection MRAM), and a charge storage memory, for example, a floating gate memory or a charge trap memory may be also used as the storage element. Using a ReRAM, which requires a smaller amount of rewriting current, has an advantageous effect that the number of storage elements included in one memory chain MU can be increased, and the semiconductor storage device 101 having a large capacity can be realized. In addition, using an STT-MRAM, which has a higher rewriting speed, has an advantageous effect that the semiconductor storage device 101 having a high data writing rate can be realized. In the present exemplary embodiment, the case where a phase change element is used as a storage element is described.

Writing and erasing are performed by passing a writing current through a phase change element PCM and thereby generating a Joule heat. The writing current is, for example, 40 uA, and an erasing current is, for example, 20 uA. It is theoretically also possible to perform the writing and the erasing by passing a current through an adjacent Z selection MOS and thereby generating a Joule heat.

In writing, a writing current of, for example, 40 uA, flows in a selected memory chain MC. Meanwhile, almost no current flows in an unselected memory chain MC.

In erasing, it is preferable that all the bits included in a memory chain MC is simultaneously erased (bundle erasing) for a plurality of memory chains MC. When it is attempted to erase only a portion of the memory chain, it often happens that a memory cell adjacent to an erasing area is subjected to erasing by error. By employing bundle erasing, the semiconductor storage device 101 with a high reliability can be realized. Further, in the case where a plurality of memory chains are collectively subjected to erasing, by using heat emission from one memory chain, an adjacent memory chain can be heated, or heat loss can be reduced, and thus an electrical energy required for the erasing can be reduced and the semiconductor storage device 101 capable of performing erasing at a high speed can be realized. The heat loss can be reduced because the temperature difference between memory chains is reduced by a memory chain adjacent to a certain memory chain being heated, and a heat flux between memory chains is reduced in accordance with a Fourier's law that a heat flux density is proportional to a temperature difference. Further, it is desirable that, in bundle erasing, the current is mainly passed through the Z selection MOS, heat is generated by its Joule heat, and thereby an erasing operation is performed. By passing the current mainly through the Z selection element ZMOS to cause the Z selection element ZMOS to generate heat, even in the case where the phase change element has a high resistance and a high voltage is required for causing the phase change element itself to generate heat, the voltage required for erasing can be reduced and a more stable heat generation amount in the erasing can be achieved.

To select a phase change element PCM, a current is passed not through the Z selection element but through the phase change element by turning the Z selection element ZMOS of the same memory cell CELL off.

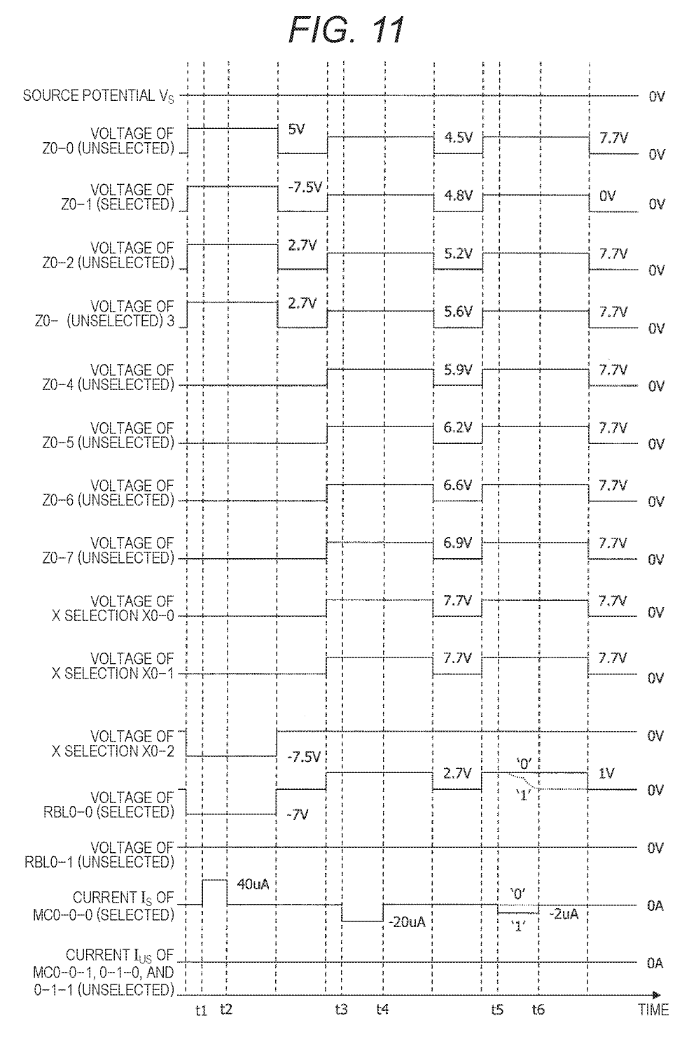

Voltage arrangements in writing, erasing, and reading will be described with reference to FIG. 11. A case where a memory cell CELL including a Z selection MOS Z0-1 of MC0-0-0 is a selected memory cell will be described as an example. A gate-source breakdown voltage of the Z selection MOS is, for example, 7.7 V.

Description about the time of writing will be given.

In a period of t1 to t2, a Y selection line not illustrated in FIG. 11 is controlled to turn a Y selection MOS on, and a writing current of, for example, 40 uA, is flowing in the memory chain MC0-0-0. At this time, the voltage of a Z selection line Z0-7 is set to 0 V.

Next, an erasing operation will be described.

In a period of t3 to t4, a Y selection line not illustrated in FIG. 11 is controlled to turn a Y selection MOS on, and an erasing current of, for example, 20 uA, is the memory chain MC0-0-0. It is desirable that the temperature of a phase change element heated by a Joule heat is lower than the temperature of the phase change in writing. In this example, a current is passed between the source and drain of a Z selection transistor ZMOS to generate a Joule heat (bundle erasing). That is, a Joule heat is generated in a channel of the Z selection transistor, and a phase change element PCM is crystallized by conveying the heat to the phase change element PCM. The gate-source voltage of a Z selection transistor ZTr is set to 4.5 V. It is desirable that the Z selection transistor ZTr is not completely on. This can increase the Joule heat generated in the Z selection transistor ZTr with the same source-drain current. To equalize the amount of generated Joule heat between memory cells, it is desirable that more detailed potential control of Z selection than in writing is performed for each layer and a gate voltage of a Z selection transistor is controlled by using at least potentials of 5 or more levels. Since the gate voltage is lower than in the case of FIG. 5, the control of gate voltage with 5 or more levels can be performed with a smaller power consumption, and the semiconductor storage device 101 with a smaller power consumption can be realized.

Phase change elements of a plurality of memory cells can be collectively subjected to erasing by bundle erasing. It is desirable that the whole of a memory chain is subjected to erasing at the same time. This is because when it is attempted to erase only a portion of the memory chain, it often happens that a memory cell adjacent to an erasing area is subjected to erasing by error. Further, it is desirable that a plurality of memory chains are collectively subjected to erasing. According to this, by using heat emission from one memory chain, an adjacent memory chain can be heated, or heat loss can be reduced, and thus an electrical energy required for the erasing can be reduced and the semiconductor storage device 101 capable of performing erasing at a high speed can be realized. The heat loss can be reduced because the temperature difference between memory chains is reduced by a memory chain adjacent to a certain memory chain being heated, and a heat flux between memory chains is reduced in accordance with a Fourier's law that a heat flux density is proportional to a temperature difference.

Here, it is desirable that the voltage of a selection bit line RBL0-0 in erasing is a positive voltage. For example, it is 2.7 V. This is because, in the case where a voltage of, for example, 2.7 to 3.6 V is supplied as a power source voltage VDD, it becomes possible to supply the voltage to be applied to a selection bit line VBL-S in erasing without using a boosting circuit by using 2.7 V, which is the minimum voltage of the power source voltage VDD, and the number of memory chains that can be simultaneously subjected to erasing can be increased to, for example, 512, by eliminating a power loss in the boosting circuit. According to this, the speed of erasing can be improved to, for example, 400 MB/s.

Next, a reading operation will be described.

It is desirable that the voltage of the selection bit line RBL0-0 in reading is positive. For example, it is 1 V. By using a positive voltage, it becomes possible to supply a power source without using a boosting circuit, and the power consumption for reading can be reduced. According to this, a semiconductor storage device 601 with a small power consumption can be provided.

In addition, since the potential of a bit line in erasing or in reading is as low as 2.7 V or 1.0 V, the semiconductor storage device 101 with a high speed can be realized.

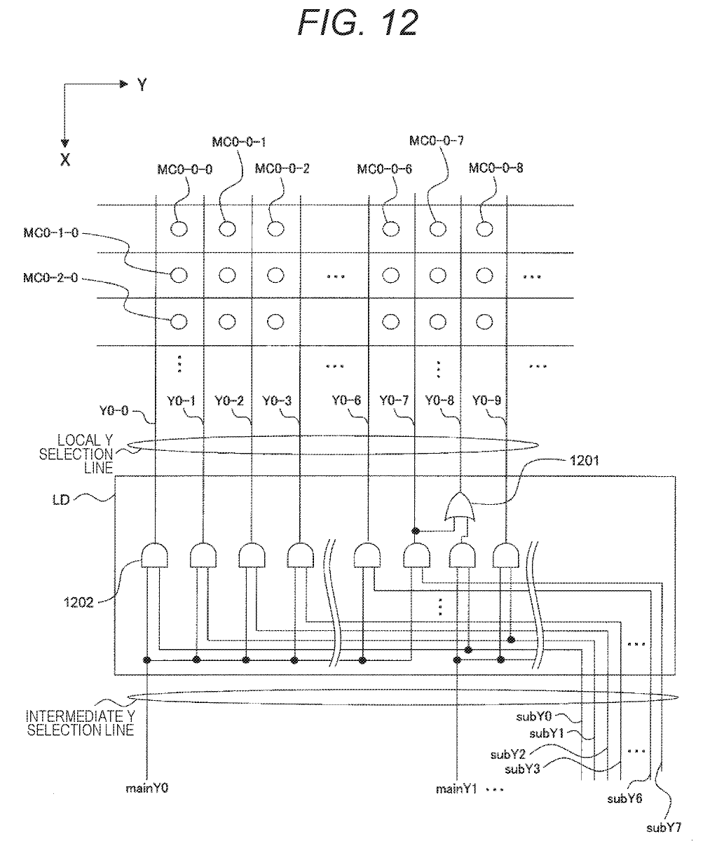

A configuration of a local driver LDG will be described with reference to FIG. 12. The local driver LDG is constituted by plural sub-local drivers LD. One of the sub-local drivers LD is illustrated in FIG. 12. The Y selection line Y0-0, which is one of local Y selection lines, is generated by an AND signal of an intermediate Y main selection line mainY0 and an intermediate Y sub-selection line subY0. That is, Y0-0 becomes ‘H’ when mainY0 and subY0 are both ‘H’, and becomes ‘L’ when mainY0 or subY0 is ‘L’.

As described above, a Y address signal is partially decoded in the global Y driver outside of the memory array, and is transmitted to a sub-local driver. Full-decoding is performed by a sub-local driver LD, and a local Y selection line Y is driven. It is desirable that, as described above, a pre-decoded signal is transmitted to a sub-local driver LD and full-decoding is performed by the sub-local driver LD. This enables reducing the number of signal lines between the global Y driver and a sub-local driver and thereby reducing the chip area compared with a case where full-decoding is performed by the global Y driver. In addition, this enables reducing the circuit area of a sub-local driver LD and thereby reducing the chip area compared with a case where full-decoding is performed by the sub-local driver LD.

Here, concerning an erasing unit, it is assumed that a region (bundle erasing region) included in a rectangle having MC(H)-8j-8k, MC(H)-8j-(8k+7), MC(H)-(8j+7)-8k, and MC(H)-(8j+7)-(8k+7) as four sides is collectively subjected to erasing. Here, H, j, and k are arbitrary integers. For example, a region included in a rectangle having MC0-0-0, MC0-0-7, MC0-7-0, and MC0-7-7 as four sides is collectively subjected to erasing. The number of bits included in the bundle erasing region is 512. In next erasing, a region included in a rectangle having MC0-0-8, MC0-0-15, MC0-7-8, and MC0-7-15 as four sides is collectively subjected to erasing. A plurality of bundle erasing regions also can be simultaneously subjected to erasing. In the description of the present exemplary embodiment, eight bundle erasing regions are simultaneously subjected to erasing. That is, erasing of 4 kbit is performed simultaneously.

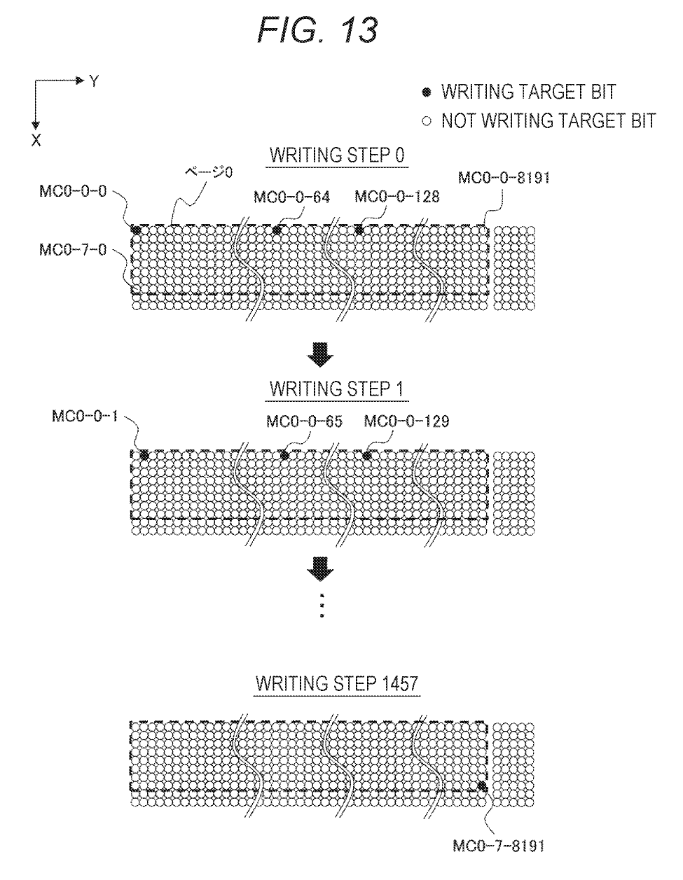

FIG. 13 illustrates examples of writing bits for respective writing steps. In these examples, a plurality of memory cells that are subjected to writing on a writing unit are dispersedly disposed at positions not adjacent to each other in the memory array. FIG. 13 illustrates change of writing targets in a memory chain MC constituting a page (8 KB) enclosed by dotted lines. Black circles are writing targets and white circles are not writing targets. It can be seen that a plurality of memory chains MC are simultaneously subjected to writing and bits adjacent to each other are not simultaneously subjected to writing. It is illustrated that MC0-0-0 and so forth are subjected to writing in a writing step 0, and MC0-0-1 adjacent thereto is subjected to writing in a writing step 1, which is the next 10 ns. To be noted, MC0-0-0 and MC0-0-1 are examples in which both are bits on which ‘0’ data is to be written, and it goes without saying that a portion of bits described above may be subjected to writing depending on the writing data. One writing step requires, for example, 10 ns. It is desirable that a resetting pulse application time is 8 ns and the time required for the selection of a Y address is 2 ns. By shortening the writing steps to approximately 10 ns, the semiconductor storage device 101 with a high data writing rate can be realized.

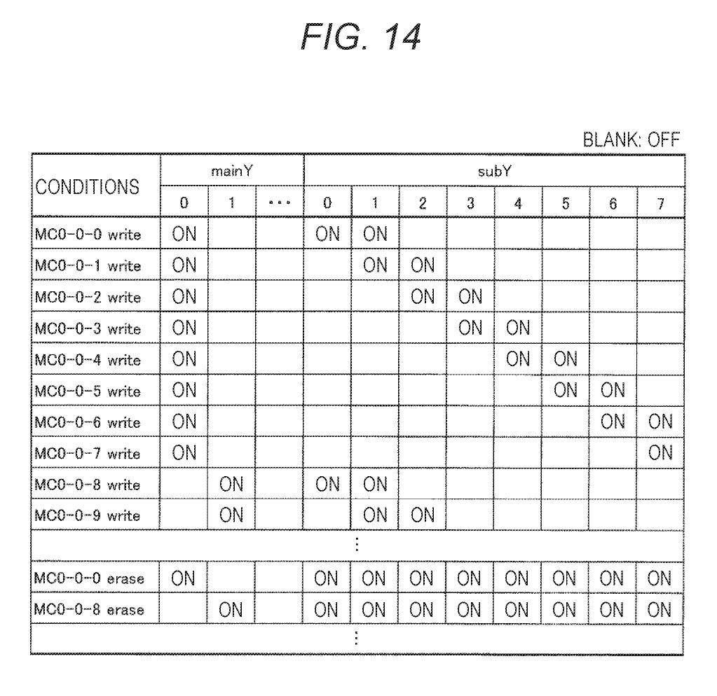

FIG. 14 illustrates states of signal lines mainY and subY at the time of selecting a bit to be subjected to writing. For example, it is illustrated that mainY0 and subY0 and 1 may be turned on to perform writing on the memory chain MC0-0-0. In addition, it is illustrated that mainY0 and subY0 to 7 may be turned on to subject a bundle erasing region (region included in the rectangle having MC0-0-0, MC0-0-7, MC0-7-0, and MC0-7-7 as four sides) including the memory chain MC0-0-0 to erasing.

A circuit configuration of the local driver LD will be described again with reference to FIG. 12. An OR circuit 1201 is provided as a circuit to drive a local Y selection line Y0-8. The OR circuit 1201 is used for subjecting a memory chain MC between a group of local Y selection lines controlled by an intermediate main Y selection line mainY0 and a group of local Y selection lines controlled by an intermediate main Y selection line mainY1 to erasing.

Signal selection at this time will be described with reference to FIG. 14. Y0-0 to Y0-8 can be selected by turning mainY0 and subY0 to 7 on to subject the bundle erasing region (region included in the rectangle having MC0-0-0, MC0-0-7, MC0-7-0, and MC0-7-7 as four sides) including the memory chain MC0-0-0 to erasing, and thereby bundle erasing can be performed.

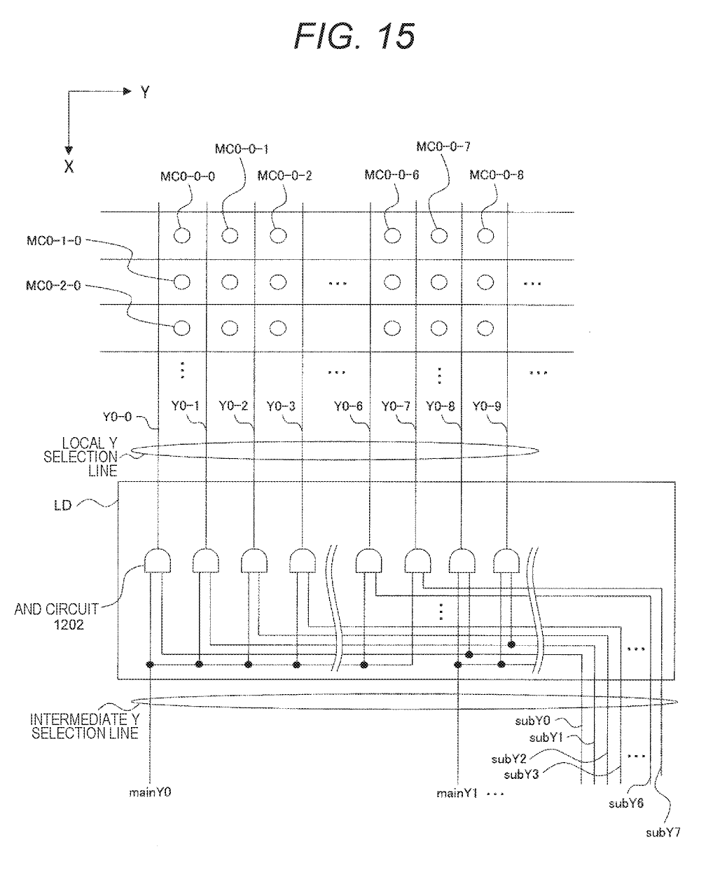

FIG. 15 illustrates a circuit diagram of a local driver not including the OR circuit 1201 described above for comparison. Since Y0-0 to Y0-7 cannot be selected even by turning mainY0 and subY0 to 7 on, MC0-0-7 or MC0-7-7 cannot be subjected to erasing. This means that a region from which or on which data cannot be erased or written is present.

That is, the OR circuit 1201 can eliminate the region from which or on which data cannot be erased or written and thereby increase the capacity of the semiconductor storage device 101.

It goes without saying that NAND logic may be used in place of AND logic. In this case, inverted values are input to the intermediate Y main selection line mainY and the intermediate Y sub-selection line subY. Using the NAND logic has a merit of reducing the circuit area and thereby realizing the semiconductor storage device 101 of a small chip area.

Further, it goes without saying that a combination of a NAND circuit and an inverter circuit may be used in place of an OR circuit.

It goes without saying that a Y selection line between sub-local drivers may be driven by a signal of an adjacent sub-local driver generated by using an OR circuit. This method enables eliminating a region that cannot be subjected to erasing between sub-local drivers and thereby increasing the storage capacity of the semiconductor storage device 101.

Further, it is desirable that addressing for the semiconductor storage device 101 of the present invention is performed using local X selection lines X, and addressing and designating of ‘0’ writing data are performed using local Y selection lines Y. According to this, it becomes possible to reduce the number of signal lines and thereby reducing the chip area of the semiconductor storage device 101 compared with a method of performing addressing using the local X selection lines X and local Y selection lines Y and designating the ‘0’ writing data using data lines.

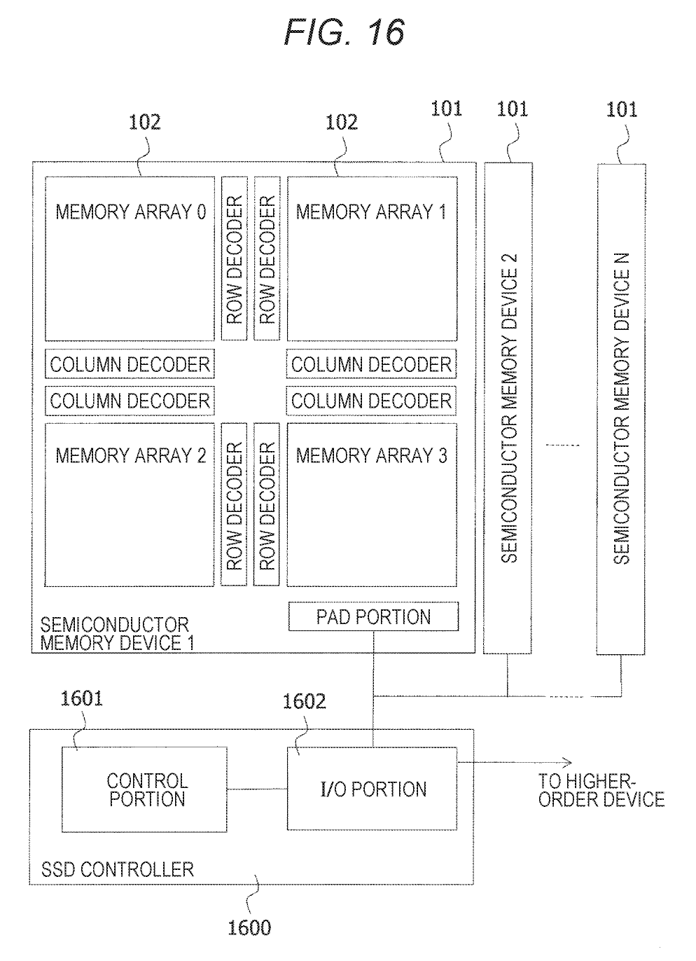

A chip layout of the semiconductor storage device 101 of the present exemplary embodiment and a configuration of a storage device including this semiconductor storage device will be described with reference to FIG. 16. FIG. 16 illustrates the semiconductor storage device 101 including a plurality of memory arrays 102. The semiconductor storage device 101 is connected to a controller 1600 via a pad portion. In addition, an X address is selected by a row decoder.

A storage device like this (SSD) can include a plurality (for example, N) of semiconductor storage devices 101 each constituted by one chip. These semiconductor storage devices are controlled by a control portion 1601 through a bus and via an I/O portion 1602 of a controller 1600. The controller 1600 is connected to a higher-order device that is not illustrated via the I/O portion 1602. Data to be recorded and commands for writing, reading, verifying, erasing, and so forth are transmitted from the higher-order device, and the controller 1600 controls the semiconductor storage device 101 in accordance with these.

In addition, as has been already described, the controller 1600 can also perform control of inverting ‘1’ values and ‘0’ values of the data received from the higher-order apparatus and recording on the semiconductor storage device 101. This can substantially reduce the number of memory cells whose states are rewritten. For example, it is assumed that, in an erased state where all the memory cells are “1”, the higher-order device instructs that data of “0” is recorded on all of these. At this time, the controller 1600 inverts the ‘1’ values and ‘0’ values of the data and causes ‘1’ to correspond to a recording state and ‘0’ to correspond to an erased state. In this case, an actual recording operation does not have to be performed. In this way, control of transmitting relatively more ‘1’ values than ‘0’ to the semiconductor storage device 101 is possible. This control can be performed by the controller 1600 internally counting the ‘1’ values and ‘0’ values and inverting the data when the number of ‘0’ is large, and thus the control can be hidden from the higher-order device.

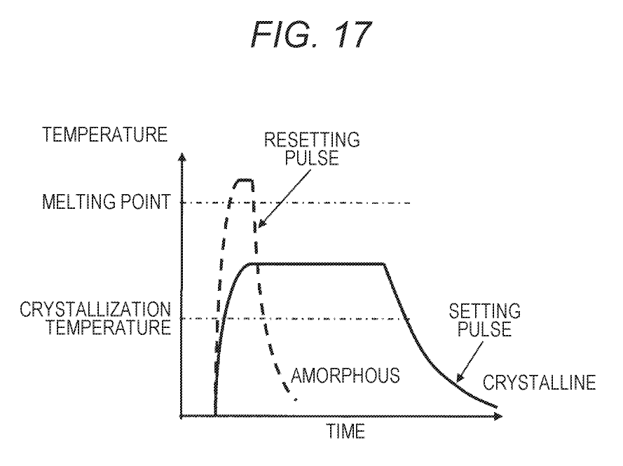

Writing and erasing for a phase change element PCM will be described with reference to FIG. 17. Writing is performed by passing a resetting pulse through a phase change element PCM and thereby generating a Joule heat. The phase change element PCM is heated to a melting point or a higher temperature by the resetting pulse, and takes an amorphous state by being quickly cooled down. The application time of the resetting pulse is, for example, 8 ns. In addition, erasing is performed by passing a setting pulse through a ZMOS, which is a Z selection MOS, and thereby generating a Joule heat. The phase change element PCM is kept at or above a crystallization temperature for a certain period, for example, 500 ns, by the setting pulse. As a result of this, the phase change element PCM takes a crystalline state. The crystalline state is lower in resistance than the amorphous state, and information can be recorded by using the difference in resistance, for example, by setting a low-resistance state as ‘1’ and a high-resistance state as ‘0’.

The present control method is particularly suitable for a memory that requires a large amount of writing current for rewriting of bits and whose data writing rate is largely affected by the amount of writing current. For example, a NAND flash memory requires a small amount of writing current for rewriting of bits and the data writing rate thereof is not affected by the amount of writing current. Meanwhile, the data writing rates of a phase change memory, an STT-RAM, and ReRAM are largely affected by the writing current, and therefore the present control method is suitable for these.

### Second Exemplary Embodiment

In the present exemplary embodiment, an example of a semiconductor recording device that has a high data writing rate even though a memory element that potentially causes a writing error.

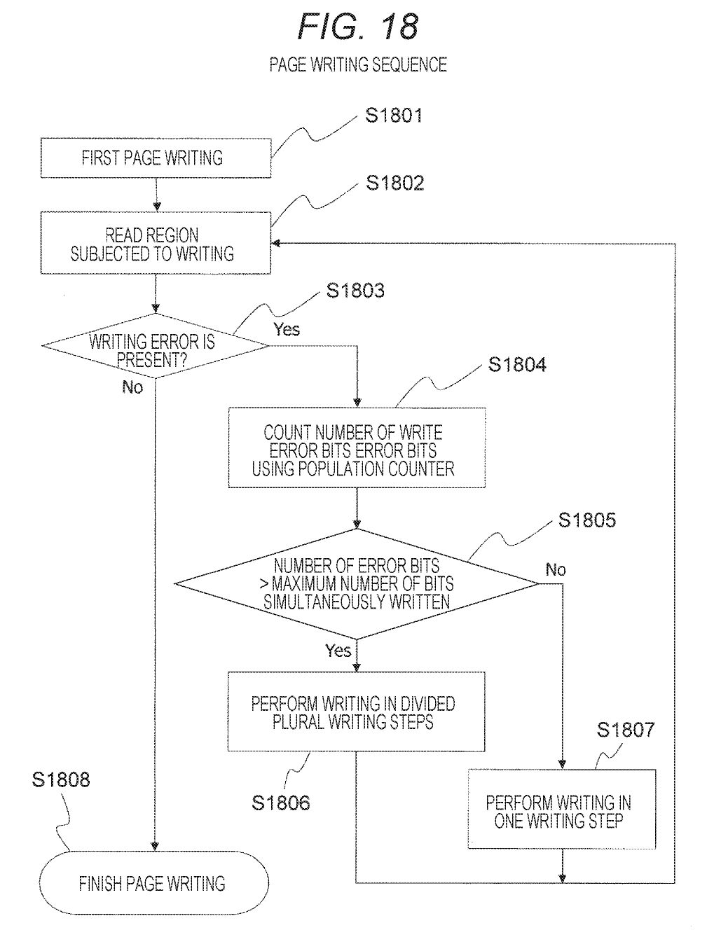

FIG. 18 is a flowchart illustrating an exemplary operation sequence according to a second exemplary embodiment of the present invention.

For the semiconductor storage device 101 that uses the memory element potentially causes a writing error, it is desirable that, in page writing of performing writing for one page, processing of reading, after attempting an writing operation for the one page, data of the region on which the writing operation has been attempted, checking whether the writing has been successful, and, in the case where the writing has been unsuccessful, performing writing again are executed. Although this may cause a writing error, this enables using a memory element that can be developed in a short period, and can realize development of the semiconductor storage device 101 in a short period.

Here, the first attempt on the writing operation is referred to as the first writing, the data reading on the region on which the writing operation has been attempted is referred to as verify-reading, and the re-writing in the case where the writing has been unsuccessful is referred to as verify-writing.

For example, a phase change memory performs a writing operation by heating up to a melting point or a higher temperature as illustrated in FIG. 17. However, the temperature to be reached varies depending on the properties of the phase change element, for example, the film thickness, even when the same writing current is passed through the phase change element PCM. Even by using the same writing current, one phase change element PCM may be heated to an appropriate temperature, another phase change element PCM whose film thickness of the phase change material is thin may greatly exceed the melting point and reach a temperature at which the memory cell CELL is broken, and yet another phase change element PCM whose film thickness of the phase change material is thick may not reach the melting point and be unsuccessful in writing. Further, for example, the variation in film thickness may be exhibited as the thickness being particularly large or small at a specific position or a specific page of the chip. To prevent the breaking of the memory cell CELL, it is desirable that the first writing is performed at a slightly lower writing current in the whole of the semiconductor storage device 101. However, this further increases the ratio of phase change elements PCM that cannot be heated enough in the first writing.

To describe the outline of the semiconductor storage device 101 described in the present exemplary embodiment, verify-reading is performed after performing the first writing of one page, the number of writing error bits is counted by using the population counter in the case where a writing error as occurred, and performing writing in one writing step in the case where the number of error bits is equal to or smaller than the maximum number of bits that can be simultaneously written. The writing is performed in plural writing steps in the case where the number of error bits is larger than the number of bits that can be simultaneously written.

The details of the present operation will be described with reference to FIG. 18.

First, the first writing for one page is performed (S1801). Collectively performing the first writing for one page enables reducing the number of times of switching between writing and reading, and thereby shortening a switching time and increasing the data writing rate. The present method is particularly effective for the semiconductor storage device 101 that uses a negative voltage for a writing electrode WR in writing and a positive voltage for a voltage to be precharged in read bit lines in reading because its switching time between writing and reading is long.

It goes without saying that it is possible to perform verify-reading after performing the first writing on a portion of the page and then perform the first writing on the remaining portion. For example, by performing the first writing, verify-reading, and verify-writing is performed in this order for an X address 0 and subsequently performing the first writing, verify-reading, and verify-writing in this order for an X address 1, it becomes possible to reduce the number of times of selection of an X address, shorten an X address selection time, and realize the semiconductor storage device 101 with a high data writing rate.

Verify-reading is performed next (S1802), and whether there is a writing error is determined by comparing a read value and a value to be written stored in the register (S1803). In the case where there is a writing error, the population counter counts the number of error bits (S1804). At this time, it is preferable to, for a region that can be subjected to writing at the same time, the number of error bits included in the region. For example, the sub-local driver LD illustrated in FIG. 12 cannot simultaneously perform writing on, for example, MC0-0-4 and MC0-0-10 due to restriction in writing bit designation derived from a pre-decoding method. Therefore, it is preferable that the number of error bits for these bits are counted separately.

Next, the number of error bits and the maximum number of bits that can be simultaneously written are compared. In the case where it is possible to perform simultaneous writing in one step from the viewpoint of electrical power, that is, where the number of error bits and the maximum number of bits that can be simultaneously written are not reached, the writing is performed in one writing step. The writing is performed in plural writing steps in the case where the number of error bits is larger than the number of bits that can be simultaneously written.

The present control method is particularly suitable for a memory for which a substantially constant writing success rate cannot be expected in writing, for example, not a charge storage type, to which charges can be injected gradually, but a phase change type memory, whose temperature is reduced approximately to the room temperature after writing and which requires to be heated again from the approximate room temperature in rewriting, a memory that utilizes spin inversion, or a filament-formation-rupture-type memory in which a subtle movement of an atom causes a great change in resistance. That is, the present control method is suitable for a phase change memory, an STT-RAM, and a ReRAM. Further, the present control method is particularly suitable for a memory that requires a large amount of writing current for rewriting of bits and whose data writing rate is largely affected by the amount of writing current. For example, a NAND flash memory requires a small amount of writing current for rewriting of bits and the data writing rate thereof is not affected by the amount of writing current. Meanwhile, the data writing rates of a phase change memory, an STT-RAM, and ReRAM are largely affected by the writing current, and therefore the present control method is suitable for these.

By shortening the time required for verify-writing while restricting the peak current at or below a certain level by using the present proposed method, the semiconductor storage device 101 with a high data writing rate can be realized.

As described above, in the third exemplary embodiment, verify-writing in the case where verification of stored data after data writing is performed by regarding a plurality of memory cells including a first memory state and a second memory state by using a difference in electrical resistance and a predetermined number of the memory cells as a writing (or setting) unit and there is an error is assumed. A counter circuit that counts the number of first memory states to be subjected to verify-writing to a writing unit in verify-writing is provided, and one or plural writing units are selected on the basis of a calculation result by the counter circuit such that the number of first memory states is equal to or smaller than a predetermined number, and the selected one or plural verify-writing units are collectively subjected to writing.

### Third Exemplary Embodiment

In the present exemplary embodiment, an example of a semiconductor recording device capable of direct overwriting (sometimes referred to as bit-alternative writing) that has a high data writing rate and does not require an erasing operation will be described.

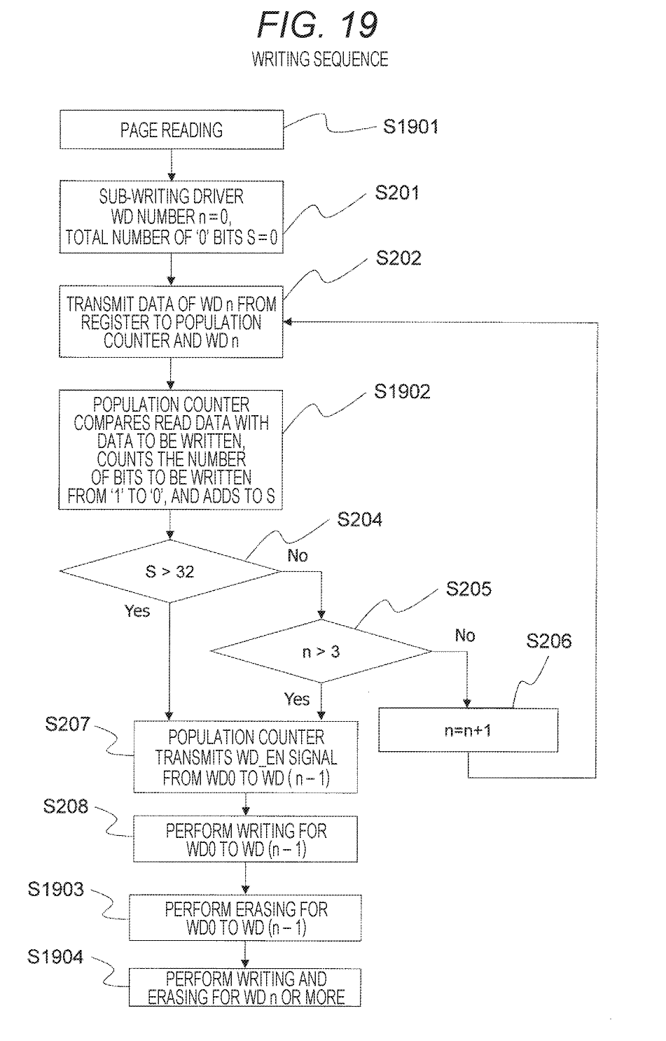

FIG. 19 is a flowchart illustrating an exemplary operation sequence according to a third exemplary embodiment of the present invention.

In the present exemplary embodiment, a case where a ReRAM capable of direct overwriting is used will be described as an example. In the ReRAM capable of direct overwriting, when writing or erasing is performed on a certain bit, values recorded on bits in the vicinity of the bit do not change often. At this time, an external controller that controls the semiconductor storage device 101, for example, an SSD controller, is capable of issuing a writing instruction without issuing an erasing instruction to the semiconductor storage device 101. It is desirable that the values of ‘0’ or ‘1’ recorded on the semiconductor storage device 101 can be rewritten into either of ‘0’ and ‘1’ by the external controller. This configuration eliminates the need for the external controller to issue the erasing instruction, and realizes a storage system capable of performing data writing processing at high speed.

In the semiconductor storage device 101, an erasing operation of rewriting data from ‘0’ to ‘1’ and a writing operation of rewriting data from ‘1’ to ‘0’ are performed. At this time, it is desirable that data of a writing target page is read before writing, which bit needs writing or erasing is investigated, and only the bit is subjected to writing or erasing and writing and erasing are not performed on bits whose values are not to be changed. This configuration reduces the number of bits subjected to writing or erasing and realizes the semiconductor storage device 101 with a high data writing rate.

To describe the outline of the exemplary embodiment of the present proposal, in page writing, page reading is first performed and, concerning writing, the population counter compares read data with data to be written, counts the number of bits to be to be subjected to writing from ‘1’ to ‘0’, and drives as many sub-writing drivers WD as possible such that this number of bits is equal to or smaller than the maximum number of bits that can be simultaneously written. It goes without saying that the same control can be performed for the erasing operation. At this time, the population counter compares read data with data to be written, counts the number of bits to be subjected to erasing from ‘0’ to ‘1’, and drives as many sub-erasing drivers WD as possible such that this number of bits is equal to or smaller than the maximum number of bits that can be simultaneously erased.

The operation sequence will be specifically described with reference to FIG. 19.

First, page reading is performed (S1901). Next, the number of bits that needs writing is counted by using the population counter (S1902), and writing is performed by driving as many sub-writing drivers WD that are acceptable from the viewpoint of the maximum peak current (S208). Subsequently, erasing is performed (S1903), and remaining writing and erasing for the page are performed (S1904).

The register can store data in three values of ‘0’ writing, ‘1’ erasing, and ‘2’ no change in values. In this way, the size of data in the register can be reduced to ¾ compared with the case where two two-value registers of a register that holds a read value and a register that holds a value to be written are provided.

The constituents expressed in singular forms in the present description include plural forms unless explicitly indicated in the context.

The present invention is not restricted to the exemplary embodiments described above, and includes various modifications. For example, part of the configuration of one exemplary embodiment may be replaced by an element of another exemplary embodiment, and an element of another exemplary embodiment may be added to the configuration of one exemplary embodiment. In addition, for the configuration of each exemplary embodiment, addition, erasing, and replacement of an element of another exemplary embodiment may be performed.

### REFERENCE SIGNS LIST

101 semiconductor recording device
102 memory array
103 population counter
104 row decoder
105 I/O portion
107 register
108 data bus
109 reading circuit
110 erasing circuit
401 population counter process
901 Z selection transistor gate electrode
902 interlayer insulation film
903 gate oxide film
904 silicon channel
905 phase change material
906 silicon oxide film
CELL memory cell
F minimum processing dimension
Local Y driver Y selection-line driving circuit
MC memory chain
mainY intermediate Y main selection line signal
PCM phase change element
RBL read bit line
SL source line
subY intermediate Y sub-selection line signal
WD sub-writing driver
WD_EN sub-writing driver activation signal
WDG writing driver group
WR writing electrode
X local X selection line
XMOS X selection element
Y local Y selection line
YMOS Y selection element
Z Z selection line
ZMOS Z selection element

1. A semiconductor storage device comprising:
a plurality of memory cells capable of setting a first memory state and a second memory state by using a difference in electrical resistance; and
a counter circuit that counts, while regarding a predetermined number of the memory cells that are a part of the plurality of memory cells as a writing unit, for a plurality of writing units, a number of memory cells whose memory state is changed when at least one (hereinafter referred to as setting) of writing (write), erasing, and verify-writing is performed on the memory cells in the writing unit,
wherein one or plural writing units are selected on a basis of a calculation result by the counter circuit such that the number of memory cells is equal to or smaller than a predetermined number, and data of the selected one or plural writing units are collectively subjected to the setting.

2. The semiconductor storage device according to claim 1, wherein the counting by the counter circuit and the setting are performed simultaneously.

3. The semiconductor storage device according to claim 1, wherein a processing time of the counter circuit satisfies the following expression:
setting time>processing time of counter circuit×maximum number of setting units simultaneously driven.

4. The semiconductor storage device according to claim 1, wherein the plurality of memory cells subjected to the setting on the writing unit are disposed in a dispersed manner at positions not adjacent to each other in a memory array.

5. A semiconductor storage device comprising:
a plurality of memory cells capable of storing a plurality of memory states;
a plurality of sub-writing drivers connected to a predetermined number of memory cells among the plurality of memory cells and capable of changing memory states of the predetermined number of memory cells;
an input path for inputting data to the sub-writing drivers; and
a counter that counts a number of memory cells whose memory states are to be changed by the plurality of sub-writing drivers on a basis of the input data among the predetermined number of memory cells,
wherein an operation timing of the plurality of sub-writing drivers is controlled on a basis of a counting result of the counter.

6. The semiconductor storage device according to claim 5, wherein the counter counts, for each of the plurality of sub-writing drivers, the number of memory cells whose memory states are to be changed, adds up results of the counting, and, in a case where the results of the counting that have been added up exceeds a first predetermined threshold value at an n-th (n is a natural number) sub-writing driver, collectively causes sub-writing drivers with ordinal numbers equal to or smaller than n−1 to operate.

7. The semiconductor storage device according to claim 6, wherein, in a case where the results of the counting that have been added up does not exceed the first predetermined threshold value at the n-th (n is a natural number) sub-writing driver but the n has reached a second predetermined threshold value, sub-writing drivers with ordinal numbers equal to or smaller than n are collectively caused to operate.

8. The semiconductor storage device according to claim 6, wherein counting for the sub-writing drivers with ordinal numbers equal to or larger than n is performed in parallel while the sub-writing drivers with ordinal numbers equal to or smaller than n−1 are collectively caused to operate.

9. The semiconductor storage device according to claim 1, wherein the predetermined number of memory cells connected to the sub-writing drivers are dispersedly disposed.

10. A storage device comprising:
a semiconductor storage device; and
a controller that controls the semiconductor storage device,
wherein the semiconductor storage device comprises:
a plurality of memory cells capable of storing a plurality of memory states by using a difference in electrical resistance;
a plurality of sub-writing drivers connected to a predetermined number of memory cells among the plurality of memory cells and capable of changing memory states of the predetermined number of memory cells;
an interface for communicating with the controller to input data to the sub-writing drivers; and
a counter that counts a number of memory cells whose memory states are to be changed by the plurality of sub-writing drivers on a basis of the input data among the predetermined number of memory cells,
wherein the controller comprises:
an I/O portion for communicating with the semiconductor storage device and a higher-order device; and
a control portion that controls at least one of writing, erasing, and verification of data for the semiconductor storage device, and
wherein an operation timing of the plurality of sub-writing drivers is controlled on a basis of a counting result of the counter.

11. The storage device according to claim 10, wherein the counter counts, for each of the plurality of sub-writing drivers, the number of memory cells whose memory states are to be changed, adds up results of the counting, and, in a case where the results of the counting that have been added up exceeds a first predetermined threshold value at an n-th (n is a natural number) sub-writing driver, collectively causes sub-writing drivers with ordinal numbers equal to or smaller than n−1 to operate.

12. The storage device according to claim 10, wherein the controller inverts a first value and a second value of data received from the higher-order device and performs control for causing the inversion to be reflected on the memory cells of the semiconductor storage device.

13. The storage device according to claim 10, wherein, in writing of data, the sub-writing drivers perform data writing of changing a state of a designated memory cell from a first value to a second value among the predetermined number of memory cells that has been subjected to erasing by being wholly set to the first value, and the counter counts a number of the memory cells to be changed from the first value to the second value.

14. The storage device according to claim 10, wherein the sub-writing drivers perform verify-writing of changing memory cells that have not been correctly changed to the second value among the memory cells to be changed from a first value to a second value to the second value again in verify-writing performed in a case where verification of stored data is performed after data writing and an error is found, and the counter counts the number of memory cells that have not been correctly changed to the second value.

15. The storage device according to claim 10, wherein the sub-writing drivers perform data writing or erasing of changing a state of a designated memory cell on the basis of the input data in the writing or erasing of the data, and the counter compares data based on a current state of a memory cell with the input data, and counts the number of memory cells to be changed from a first value to a second value for performing the data writing or erasing on a basis of the input data.
